(19) United States
(12) Patent Application Publication
(10) Pub. No.: US 2017/0345981 A1
(43) Pub. Date: Nov. 30, 2017

(54) LIGHT-EMITTING DEVICE

(71) Applicant: Sanken Electric Co., Ltd., Niiza-shi (JP)

(72) Inventors: Tetsuji MATSUO, Niiza-shi (JP); Yasuhiro MARUO, Niiza-shi (JP)

(73) Assignee: Sanken Electric Co., Ltd., Niiza-shi (JP)

(21) Appl. No.: 15/659,700

(22) Filed: Jul. 26, 2017

Related U.S. Application Data
(63) Continuation of application No. PCT/JP2016/065973, filed on May 31, 2016.

(51) Int. Cl. H01L 33/56; H01L 33/60; H01L 33/38; H01L 33/54

(52) U.S. Cl. CPC H01L 33/56; H01L 33/387; H01L 33/60; H01L 33/385; H01L 33/54

(57) ABSTRACT

The device is comprised of a backing board, a light-emitting element disposed on the backing board having a laminate structure in which a second semiconductor layer is disposed above a first semiconductor layer, a light-permeable board disposed over the light-emitting element, a first connecting electrode ranging from a first side face of the backing board to a first side face of the light-permeable board and electrically connected to the first semiconductor layer, and a second connecting electrode ranging from a second side face of the backing board to a second side face of the light-permeable board and electrically connected to the second semiconductor layer, wherein connection to the mounting board is established via a second side face of the first connecting electrode and the second connecting electrode, the second side being opposed to a first side face looking to the backing board and the light-permeable board.

### CROSS-REFERENCE TO RELATED APPLICATIONS

This application is a Continuation application of PCT International Application No. PCT/JP2016/065973 (filed May 31, 2016), the entire contents of which are incorporated herein by reference.

### BACKGROUND

### Technical Field

The disclosure herein relates to a light-emitting device to which a chip size package technology is applied.

### Description of the Related Art

For the purpose of improvement of emission efficiency or size reduction of a light-emitting device using a light-emitting element such as a light-emitting diode (LED) as a light source, a chip size package (CSP) is applied to a light-emitting device (see PTL 1 for example). In order to realize a smaller size semiconductor light-emitting device, a structure in which a semiconductor substrate used in a semiconductor layer constituting a light-emitting element is separated from the semiconductor layer and the semiconductor layer is put into a package of a resin or such is under development.

In a light-emitting device to which CSP is applied, electrodes connected to the light-emitting element are disposed on a lower face opposed to a face from which the light is extracted. Thus, as there's no obstacle shading outgoing light out of the light-emitting element in a direction where the light is extracted, the emission efficiency of the light-emitting device is improved. For this purpose, electrodes connected to a wiring pattern disposed on a mounting board on which the light-emitting device is installed are disposed on a lower face of the light emitting device. The electrodes of the light-emitting device and the wiring pattern disposed on the mounting board are in general connected by means of solder.

### CITATION LIST

### Patent Literature

### PTL 1: Japanese Patent Application Laid-open No. 2014-150196

### SUMMARY

If the electrodes of the light-emitting device are disposed on the lower face, however, bonding components for connecting the light-emitting device and the mounting board inherently becomes thin and therefore strength of bonding becomes weak. In a case of solder bonding for example, escape of the flux components out of the solder would be worsened or voids could be formed in the solder, so that the strength of bonding would become weak. Further, in the solder bonding, the self-alignment effect would be expected, in which substances would be automatically set in place in the course of solder fusion and subsequent solidification, however, the self-alignment effect would come to be insufficient in a case where the solder is thin. Therefore, as the light-emitting device would be displaced in the course of solder bonding, it gives rise to a risk in which some malfunction such as poor contact would occur.

Any device disclosed herein has created in view of the aforementioned problems to provide a light-emitting device, which can be stably installed on a mounting board and to which CSP is applied.

According to an embodiment, provided is a light-emitting device connected to a mounting board comprised of a backing board; a light-emitting element disposed on the backing board, the light-emitting element having a laminate structure in which a second semiconductor layer is disposed above a first semiconductor layer; a light-permeable board disposed over the light-emitting element; a first connecting electrode so continuously disposed as to range from a first side face of the backing board to a first side face of the light-permeable board and electrically connected to the first semiconductor layer; and a second connecting electrode so continuously disposed as to range from a second side face of the backing board to a second side face of the light-permeable board and electrically connected to the second semiconductor layer, wherein connection to the mounting board is established via a second side face of the first connecting electrode and the second connecting electrode, the second side being opposed to a first side face looking to the backing board and the light-permeable board.

### BRIEF DESCRIPTION OF THE DRAWINGS

FIG. 1 is a schematic cross sectional view showing a structure of a light-emitting device according to an embodiment.

FIG. 2 is a schematic plan view showing the structure of the light-emitting device according to the embodiment.

FIG. 3 is another schematic plan view showing the structure of the light-emitting device according to the embodiment.

FIG. 4 is a schematic drawing showing an example in which the light-emitting device according to the embodiment is installed on a mounting board.

FIG. 5 is a schematic drawing showing an example in which a light-emitting device according to a comparative example of the prior art is installed on a mounting board.

FIG. 6 is a process cross sectional view for describing a method for producing a light-emitting device according to the embodiment (PART 1).

FIG. 7 is a process cross sectional view for describing a method for producing a light-emitting device according to the embodiment (PART 2).

FIG. 8 is a process cross sectional view for describing a method for producing a light-emitting device according to the embodiment (PART 3).

FIG. 9 is a process cross sectional view for describing a method for producing a light-emitting device according to the embodiment (PART 4).

FIG. 10 is a process cross sectional view for describing a method for producing a light-emitting device according to the embodiment (PART 5).

FIG. 11 is a process cross sectional view for describing a method for producing a light-emitting device according to the embodiment (PART 6).

FIG. 12 is a process cross sectional view for describing a method for producing a light-emitting device according to the embodiment (PART 7).

FIG. 13 is a process cross sectional view for describing a method for producing a light-emitting device according to the embodiment (PART 8).

FIG. 14 is a schematic cross sectional view showing a structure of a light-emitting device according to a modified example of the embodiment.

FIG. 15 is a schematic cross sectional view showing a structure of a light-emitting device according to another embodiment.

FIG. 16 is a schematic drawing showing an example in which the light-emitting device according to the embodiment is installed on a mounting board.

FIG. 17 is a schematic cross sectional view showing a structure of a light-emitting device according to still another embodiment.

FIG. 18 is a schematic drawing showing a structure of a light-emitting device of a filament type to which a light-emitting device according to a comparative example of the prior art is applied.

FIG. 19 is a schematic cross sectional view showing a structure of a light-emitting device according to a modified embodiment.

### DESCRIPTION OF EMBODIMENTS

Exemplary embodiment will be described hereinafter with reference to the appended drawings. In the following descriptions about the drawings, the same or similar reference signs are attached to the same or similar parts.

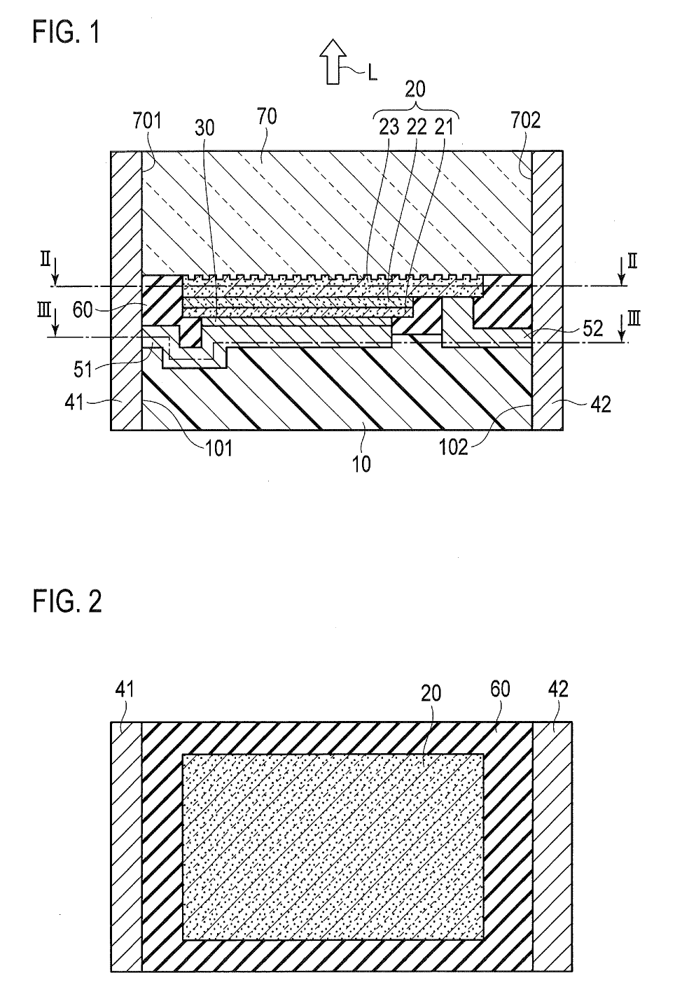

A light-emitting device according to an embodiment is, as shown in FIG. 1, comprised of a backing board 10, a light-emitting element 20 disposed on the backing board 10, which has a laminate structure in which a second semiconductor layer 23 is disposed above a first semiconductor layer 21, a light-permeable board 70 disposed above the light-emitting element 20, a first connecting electrode 41 electrically connected to the first semiconductor layer 21, and a second connecting electrode 42 electrically connected to the second semiconductor layer 23.

The first connecting electrode 41 is so continuously disposed as to range from a first side face 101 of the backing board 10 through a side face of the light-emitting element 20 to a first side face 701 of the light-permeable board 70. The second connecting electrode 42 stands apart from the first connecting electrode 41 and is so continuously disposed as to range from a second side face 102 of the backing board 10 through a side face of the light-emitting element 20 to a second side face 702 of the light-permeable board 70. In the following description, the first connecting electrode 41 and the second connecting electrode 42 are collectively referred to as “connecting electrodes”. While details will be described later, the light-emitting device shown in FIG. 1 is electrically connected to a wiring pattern disposed on a mounting board on which the light-emitting device is installed through side faces of the connecting electrodes opposed to side faces looking to the backing board 10 and the light-permeable board 70.

In the light-emitting device shown in FIG. 1, the connecting electrodes for supplying current to the light-emitting element 20 are disposed at side faces of the light-emitting device. And, below the light-emitting element 20, the backing board 10 is disposed in between the first connecting electrode 41 and the second connecting electrode 42. In the plan view, the whole of the lower face of the light-emitting element 20 is covered with the backing board 10.

The light-emitting element 20 has a laminate structure having a first semiconductor layer 21 of a first conductivity type and a second semiconductor layer 23 of a second conductivity type. The first conductivity type and the second conductivity type are counter to each other in conductivity types. More specifically, where the first conductivity type was a P-type, the second conductivity type should be an N-type. Adversely, where the first conductivity type was an N-type, the second conductivity type should be a P-type. The following exemplary description is directed to an example in which the first conductivity type is a P-type and the second conductivity type is an N-type. The light-emitting element 20 is an LED element for example, in which the first semiconductor layer 21 is a P-type clad layer and the second semiconductor layer 23 is an N-type clad layer. In the example shown in FIG. 1, applied to the light-emitting element 20 is a double-hetero-structure in which the first semiconductor layer 21, a light-emitting layer 22 and the second semiconductor layer 23 are stacked up.

Positive holes are supplied from the first connecting electrode 41 to the first semiconductor layer 21 and electrons are supplied from the connecting electrode 42 to the second semiconductor layer 23. Then the positive holes from the first semiconductor layer 21 and the electrons from the second semiconductor layer 23 are injected into the light-emitting layer 22. The injected positive holes and the injected electrons are recombined in the light-emitting layer 22 so as to generate light in the light-emitting layer 22.

In the light-emitting element 20, the principal surface of the second semiconductor layer 23 functions as a light-extraction face. Outgoing light from the light-emitting element 20 passes through the light-permeable board 70 disposed over the second semiconductor layer 23 and is then output from the light-emitting device as output light L. The light-permeable board 70 functions as an encapsulating member for the light-emitting element 20 and also as a lens for the light-emitting device.

A first led-out electrode 51 connecting the first semiconductor layer 21 of the light-emitting element 20 with the first connecting electrode 41 is electrically connected to a lower face of the first semiconductor layer 21. In the meantime, on the lower face of the first semiconductor layer 21, a reflective metal layer 30 is disposed, and the first led-out electrode 51 is electrically connected via the reflective metal layer 30 to the first semiconductor layer 21. The first led-out electrode 51 is elongated in a direction perpendicular to a direction of lamination of the light-emitting element 20 and connected to the first connecting electrode 41 disposed on the side face of the light-emitting element 20.

The outgoing light going in a direction from the light-emitting element 20 toward the first semiconductor layer 21 is reflected on the surface of the reflective metal layer 30. More specifically, by means of the reflective metal layer 30, outgoing light from the light-emitting element 20 going in a direction opposite to the light-extraction face can be reflected toward the light-extraction face. Brightness of the output light L can be thus improved. To the reflective metal layer 30 applied is a conductive material that has a high reflectance in regard to the outgoing light from the light-emitting element 20 and has a capacity of being in ohmic contact with the first semiconductor layer 21. Any white or whitish metal film of any silver alloy such as silver-palladium is preferably applied to the material for the reflective metal layer 30.

A second led-out electrode 52 connecting the second semiconductor layer 23 of the light-emitting element 20 with the second connecting electrode 42 is electrically connected to a lower face of the second semiconductor layer 23. The second semiconductor layer 23, as shown in FIG. 1, has a region elongated in a horizontal direction to a region where the first semiconductor layer 21 and the light-emitting layer 22 are not disposed in the plan view (referred to as “elongated region” hereinafter). The second led-out electrode 52 is connected to a lower face of the elongated region of the second semiconductor layer 23. The second led-out electrode 52 is elongated in a direction perpendicular to a direction of lamination of the light-emitting element 20 and connected to the second connecting electrode 42 disposed on the side face of the light-emitting element 20.

In the meantime, a protective film 60 so disposed as to cover the side face and the lower face of the light-emitting element 20 insulates and separates the light-emitting element 20, the connecting electrodes, the first led-out electrode 51 and the second led-out electrode 52. The protective film 60 contributes to suppression of water intrusion from the exterior into the light-emitting element and improvement of mechanical strength of the light-emitting device.

FIG. 2 shows a cross sectional plan view along a II-II direction of FIG. 1. The light-emitting device is rectangular and the side face thereof on which the first connecting electrode 41 is disposed is opposed to the side face on which the second connecting electrode 42 is disposed.

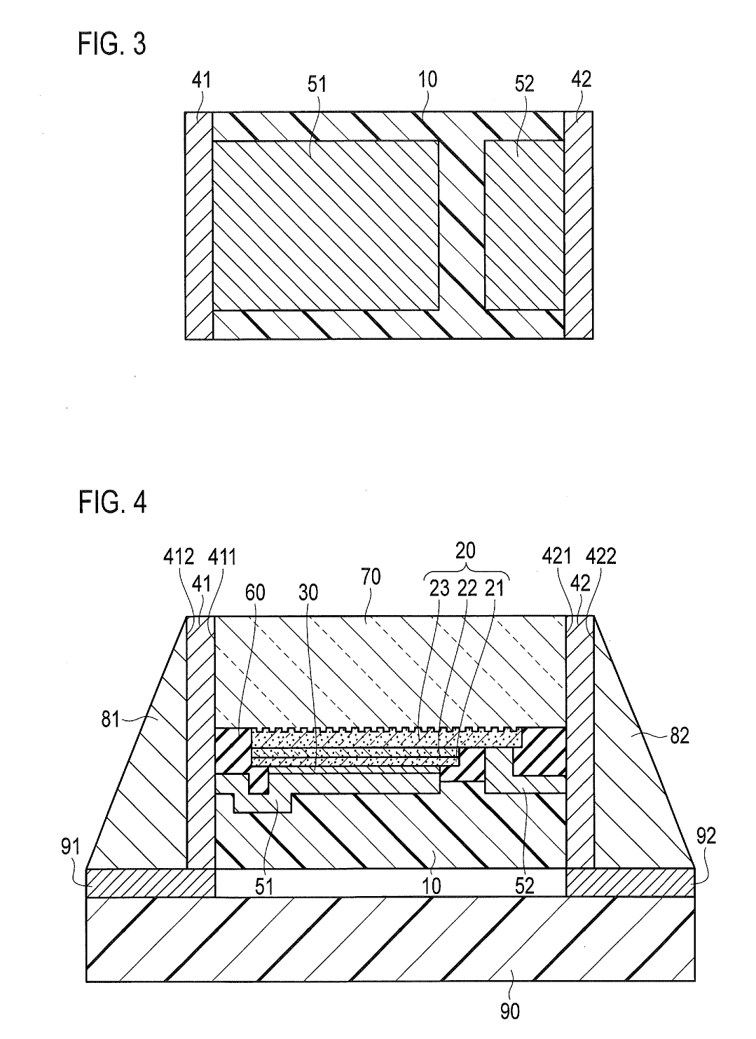

FIG. 3 shows a plan view along a direction of FIG. 1. The first led-out electrode 51 is separated from the second led-out electrode 52 by the backing board 10.

FIG. 4 shows an example in which the light-emitting device shown in FIG. 1 is installed on a mounting board 90. As shown in FIG. 4, a first bonding component 81 is disposed on a second side face 412 of the first connecting electrode 41, which is opposed to a first side face 411 looking to the backing board 10 and the light-permeable board 70. Further, a second bonding component 82 is disposed on a second side face 422 of the second connecting electrode 42, which is opposed to a first side face 421 looking to the backing board 10 and the light-permeable board 70. And, a lower face of the first connecting component 81 is connected to a first wiring pattern 91 disposed on the mounting board 90, and a lower face of the second bonding component 82 is connected to a second wiring pattern 92 disposed on the mounting board 90. To the first bonding component 81 and the second bonding component 82 (collectively referred to as “bonding components” hereinafter), an electrically conductive material is applied. For example, by means of solder bonding using a solder as a bonding component, the light-emitting device is connected to the mounting board 90.

As the light-emitting device shown in FIG. 1 has a structure to which CSP is applied and there's no obstacle shading the light from the light-emitting element 20 in a direction of the light extraction face, the emission efficiency of the light-emitting device is improved. Further, as shown in FIG. 4, as wire bonding is not used in wiring for connecting electrodes, malfunction caused by disconnection of wires or short-circuit via the wires can be suppressed. Reliability of the light-emitting device can be thus improved.

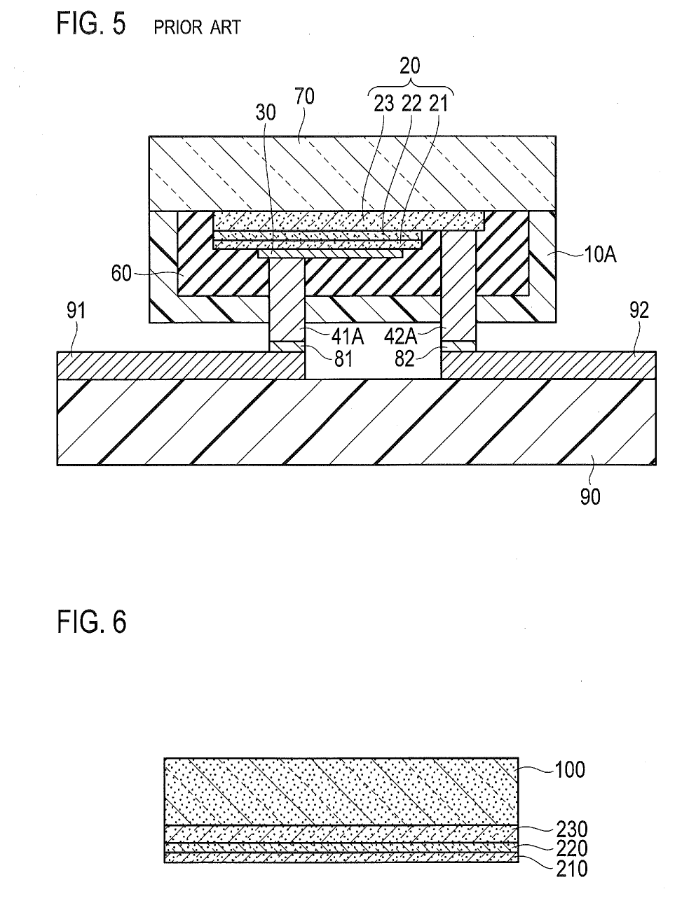

FIG. 5 shows an example in which a light-emitting device of a comparative example to which CSP is applied is installed on the mounting board 90. The light-emitting device shown in FIG. 5 is comprised of a backing board 10A provided with a concave section on its upper section, a light-emitting element 20 disposed in the concave section of the backing board 10A, and a light-permeable board 70 disposed over the light-emitting element 20. More specifically, a lower face and side faces of the light-emitting element 20 are surrounded by the backing board 10.

In the light-emitting device shown in FIG. 5, a first pillar electrode 41A penetrates a lower section of the backing board 10A and is connected to the first semiconductor layer 21 in the concave section of the backing board 10A via a reflective metal layer 30. Further, a second pillar electrode 42A, at a position apart from a position where the first pillar electrode 41A penetrates the backing board 10A, penetrates the lower section of the backing board 10A and is connected to an elongated region of the second semiconductor layer 23 in the concave section of the backing board 10A. In the remaining region in the concave section of the backing board 10A, a protective film 60 is disposed.

As shown in FIG. 5, a lower face of the first pillar electrode 41A and a first wiring pattern 91 of the mounting board 90 are connected together by means of a first bonding component 81. Further, a lower face of the second pillar electrode 42A and a second wiring pattern 92 of the mounting board 90 are connected together by means of a second bonding component 82.

In the light-emitting device of the comparative example shown in FIG. 5, as the first pillar electrode 41A and the second pillar electrode 42A are disposed below the light-emitting element 20, an area of connection of the light-emitting device with the mounting board 90 is relatively small and the bonding components are made to be thin. Therefore, in a case where solder is used as the bonding component, strength of solder bonding would be lowered and the light-emitting device would be out of place as the self-alignment effect at the time of solder bonding is insufficient.

In contrast in the configuration shown in FIG. 4, the connecting electrodes are respectively disposed on substantially whole surfaces of two side faces of the light-emitting device. As the parts for connecting are on the side faces of the light-emitting device in this way, the light-emitting device and the mounting board 90 are bonded by a sufficient amount of bonding components. Bonding strength between the light-emitting device and the mounting board 90 are thereby increased so that installation and fixation can be made stable. Further, as the amount of the bonding components can be increased at the time of product assembly, disconnection failure caused by shortage of the bonding components can be prevented and therefore reliability of the product can be improved.

In particular in a case where solder is used as the bonding components, as the surface areas of the bonding components are large, escape of flux components out of the solder would be promoted and void generation could be suppressed, so that the bonding strength is improved. Further, as the sufficient amount of the solder is used, the self-alignment effect at the time of the solder bonding can suppress misalignment of the light-emitting device.

Still further, as the connecting electrodes in the light-emitting device shown in FIG. 1 are disposed on the side faces of the light-emitting device, pillar electrodes are not necessary unlike in the case of the comparative example shown in FIG. 5. Therefore reduction in size of the light-emitting device is made possible.

In the meantime, as shown in FIG. 4, further on the side faces of the light-permeable board 70, the light-emitting device is connected to the mounting board 90 by means of the bonding components. The light-permeable board 70 is, therefore, required to have thermal resistance to a temperature for using the bonding components to form connection between the connecting electrodes and the wiring pattern on the mounting board 90. For example, in a case of solder bonding using solder as the bonding components, the light-permeable board 70 is required to have thermal resistance to a temperature of heat treatment in the solder bonding. For this reason, a glass board for example is preferably applied to the light-permeable board 70. In contrast, any resin having a heatproof temperature of 200 degrees C. or less gives rise to failure such as resin deterioration at a time of assembly by the solder bonding.

Further, by covering the whole surface of the side of the light-emitting element 20 where the light is extracted, thermal resistance can be improved and mechanical strength of the light-emitting device can be improved. By using a glass board having a higher elastic coefficient than any resin as the light-permeable board 70 for example, the mechanical strength can be improved as compared with a case where a resin board is used as the light-permeable board 70. Further, while a silicone resin has a thermal resistance to 150 degrees C. or so, the glass board has a thermal resistance to 400 degrees C. or more. Thus, by using the glass board as the light-permeable board 70, thermal resistance of the light-emitting device can be prominently improved.

To the backing board 10, a resin board such as an epoxy resin or a silicone resin can be applied. However, it is preferable to use any material having higher mechanical strength than resins for the backing board 10. For example, by using a ceramic board as the backing board 10, mechanical strength of the light-emitting device as a package can be improved. Applying the ceramic board to the backing board 10 results in sufficient thermal resistance to temperatures (400 degrees or higher) for forming the glass board as the light-permeable board 70. In contrast thereto, if a board of any material having low thermal resistance is used as the backing board 10, as the heatproof temperature of the backing board 10 becomes insufficient, the backing board 10 might melt when the glass board is formed as the light-permeable board 70. It is thus preferable to apply the ceramic board to the backing board 10.

As described above, according to the light-emitting device of the embodiment, at the connecting electrodes disposed on the side faces of the light-emitting device, the light emitting device and the mounting board 90 are bonded together by means of the bonding components. Therefore the area where the bonding components are disposed is wide and the light-emitting device and the mounting board 90 are bonded by means of a sufficient amount of the bonding components. As a result, strength of bonding between the light-emitting device and the mounting board 90 is high and the light-emitting device can be stably attached on the mounting board 90. This results in a reduced risk of damage to the light-emitting device at a time of assembly and results in improved reliability of the light-emitting device.

Further, it is preferable to use any material having higher thermal resistance than a resin for the backing board 10 and the light-permeable board 70 in order to use bonding components of solder or such at the side faces of the light-emitting device to connect the light-emitting device with the mounting board 90. Thermal resistance of the light-emitting device is thereby improved as compared with a case where any resin is applied to the light-permeable board 70 and the backing board 10. Further, by using any material such as a glass board having a high elastic coefficient for the light-permeable board 70 and using any material such as a ceramic board having high mechanical strength for the backing board 10, mechanical strength of the light-emitting device as a package can be improved.

A method for producing the light-emitting device according to the embodiment will be described below with reference to FIGS. 6-13. In the meantime, the method for producing the light-emitting device as described below is no more than an example and it is needless to say that any various production methods including its modified examples could be realized.

First, as shown in FIG. 6, respective layers constituting the light-emitting element 20 are formed on a semiconductor substrate 100 of 700 micrometers in thickness by an epitaxial growth method or such. In more detail, an N-type semiconductor film 230, a light-emitting region film 220 and a P-type semiconductor film 210 are layered in series on the semiconductor substrate 100. Any nitride compound semiconductor such as gallium nitride is applied to the N-type semiconductor film 230, the light-emitting region film 220 and the P-type semiconductor film 210. Thereafter patters are formed on the N-type semiconductor film 230, the light-emitting region film 220 and the P-type semiconductor film 210 by dry-etching to form the second semiconductor layer 23, the light-emitting layer 22 and the first semiconductor layer 21.

Next, the first semiconductor layer 21 and the light-emitting layer 22 are in part removed by a dry-etching method or such to expose a part of the second semiconductor layer 23. This exposed part is the elongated region to which the second led-out electrode 52 will be connected. Next, the protective film 60 is formed so as to cover the first semiconductor layer 21, the elongated region of the second semiconductor layer 23 and the exposed part of the light-emitting element 20.

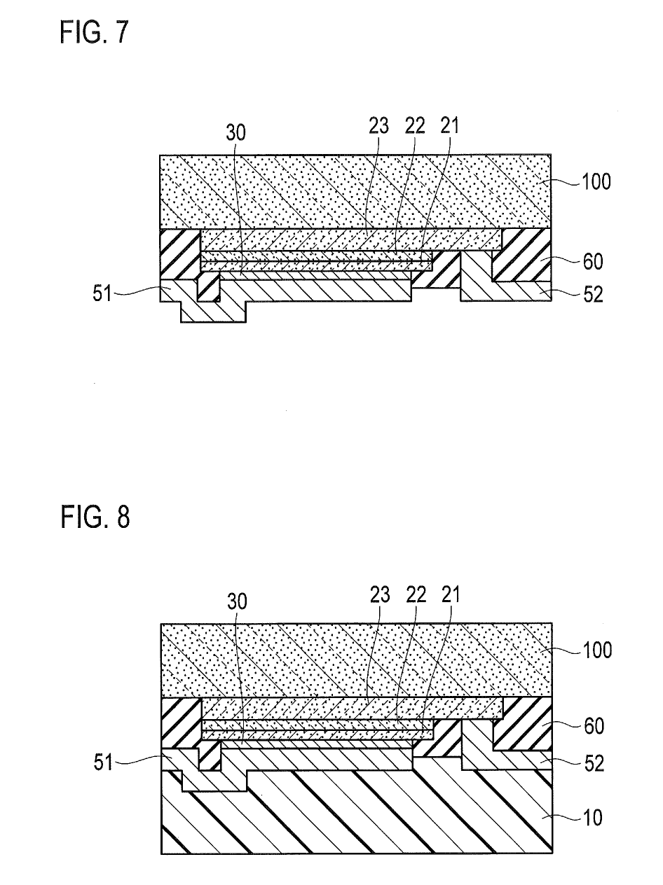

Thereafter, as shown in FIG. 7, an aperture of the protective film 60 is formed on the first semiconductor layer 21 and the reflective metal layer 30 is formed so as to connect with the first semiconductor layer 21 through the aperture. And, the first led-out electrode 51 is formed so as to connect with the reflective metal layer 30. Further, an aperture of the protective film 60 is formed on the elongated region of the second semiconductor layer 23 and the second led-out electrode 52 is formed so as to connect with the second semiconductor layer 23 through the aperture. While gold (Au) films or such are applied to the first led-out electrode 51 and the second led-out electrode 52, it is preferable to use any material that reflects the outgoing light from the light-emitting element 20. Aluminum (Al) films or silver (Ag) films may be applied thereto.

Next, as shown in FIG. 8, the backing board 10 is formed so as to cover the protective film 60, the first led-out electrode 51 and the second led-out electrode 52. For example, after putting a liquidized ceramic material thereon, the whole is sintered to form the backing board 10.

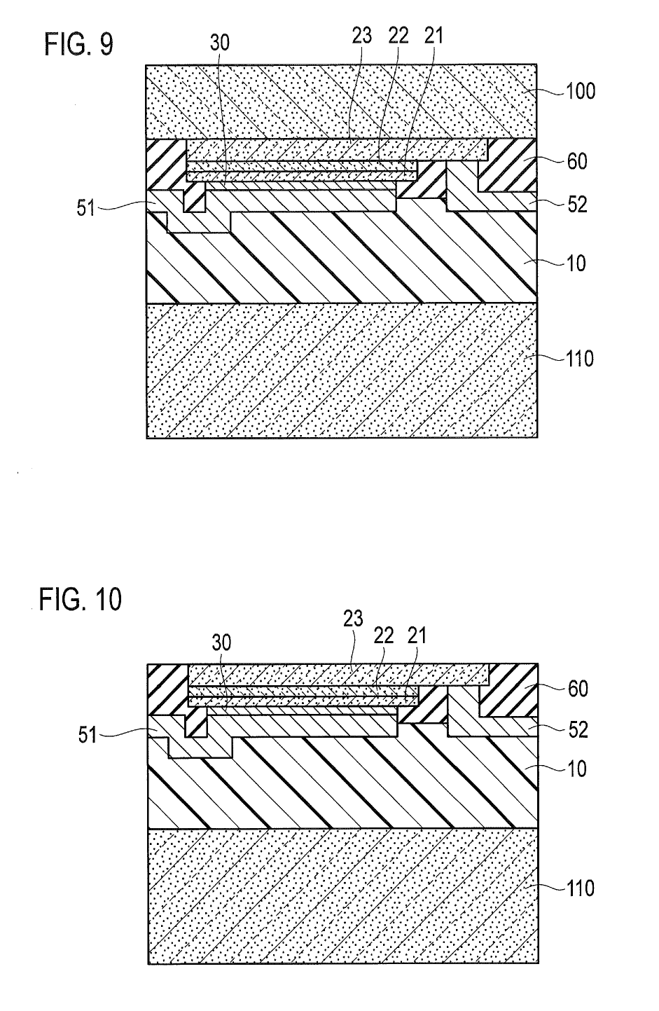

Thereafter, as shown in FIG. 9, a support board 110 that covers the lower face of the backing board 10 is formed. As a substrate in which the light-emitting element 20 and the backing board 10 are layered is only several tens micrometers in thickness, the support board 110 is formed to reinforce the substrate even after the semiconductor board 100 is removed. Any silicon board or ceramic board about 1 mm in thickness is bonded to the substrate as the support board 110.

Next, as shown in FIG. 10, the semiconductor board 100 is removed from the substrate. In a case where the semiconductor board 100 is a silicon board for example, the semiconductor board 100 is removed by wet-etching using fluonitric acid. In a case where the semiconductor board 100 is a sapphire board, a laser lift-off method is used.

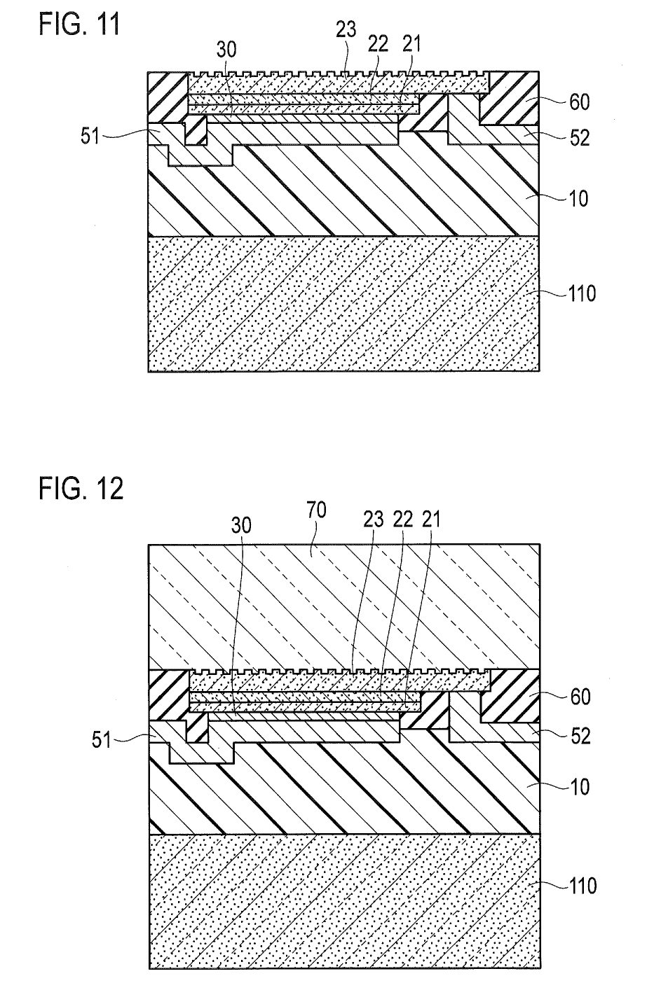

In the meantime, as shown in FIG. 11, any bumpy structure may be formed on a principal face of the second semiconductor layer 23 exposed by removal of the semiconductor board 100. By roughening the surface of the light-extraction face of the light-emitting element 20, the outgoing light from the light-emitting element 20 is diffused and brightness of the output light L is improved. The bumpy structure is formed for example by a dry-etching process using a pattern formed by a photomask or nano imprinting.

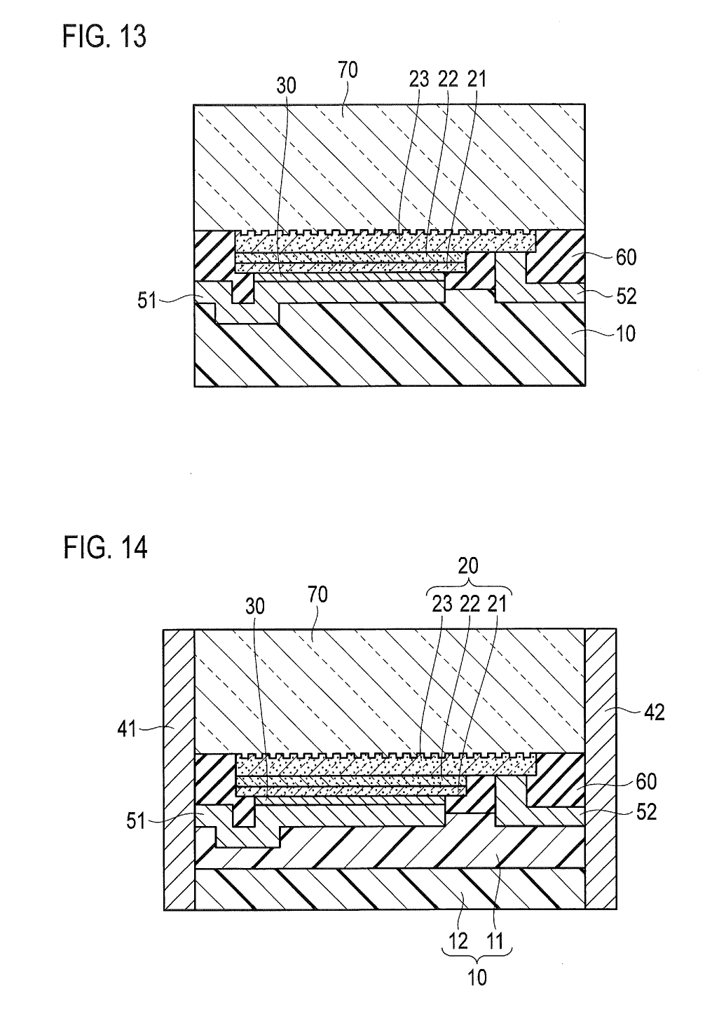

Thereafter, as shown in FIG. 12, the light-permeable board 70 is formed on the second semiconductor layer 23. Then, after a singulation process in which the wafer is reduced by dicing to individual light-emitting devices, the support board 110 is removed as shown in FIG. 13.

Next, the first connecting electrode 41 and the second connecting electrode are formed. More specifically, the first connecting electrode 41 is so formed continuously as to range from the first side face 101 of the backing board 10 to the first side face 701 of the light-permeable board 70. The first connecting electrode 41 is then connected with an end section of the first led-out electrode 51. Further, the second connecting electrode 42 is so formed continuously as to range from the second side face 102 of the backing board 10 to the second side face 702 of the light-permeable board 70. The second connecting electrode 42 is then connected with an end section of the second led-out electrode 52. The first connecting electrode 41 and the second connecting electrode 42 are formed by Au-series plating for example. Thicknesses of the first connecting electrode 41 and the second connecting electrode 42 are around several tens micrometers. By the above processes, the light-emitting device as shown in FIG. 1 is finished.

In accordance with the method for producing the light-emitting device according to the embodiment of as described above, the connecting electrodes are formed on the side faces of the light-emitting device. And, substantially on the whole surface of the connecting electrodes, the light-emitting device and the mounting board 90 are connected by means of the bonding components. As the areas where the bonding components are wide and the connection between the light-emitting device and the mounting board 90 are made by the sufficient amount of the bonding components, the light-emitting device can be stably attached to the mounting board 90.

In the meantime, by using the ceramic board as the backing board 10, the substantially whole surface of the lower face of the light-emitting device 20 is supported by the ceramic board. It can be thus suppressed to create a case where the light-emitting device 20 is damaged by deformation caused by removal of the semiconductor board 100 or such at the time of production. Further, it is prevented to create a case where the light-emitting element 20 is damage by impact on the light-emitting device at a time of assembling or handling products. By forming the backing board 10 of the ceramic board, damage of the light-emitting device and decrease in reliability can be suppressed. Further, damage by thermal distortion caused by a solder heat treatment or such at a time of product assembly can be suppressed.

And now, in the configuration of the comparative example shown in FIG. 5, it is required to expose the first pillar electrode 41A and the second pillar electrode 42A out of the lower face of the backing board 10A. Therefore, after forming the backing board 10, the lower face of the backing board 10A is ground by a grinding process (back-grinding). In a case where the ceramic board is applied to the backing board 10A, this grinding process is relatively difficult as compared with a resin board. In the light-emitting device shown in FIG. 1, however, the grinding process on the backing board 10 is unnecessary. Therefore damages by the grinding process to the backing board 10 and the light-emitting element 20 can be eliminated. Consequently reduction in yield ratio or reliability degradation can be prevented.

Further, in a light-emitting device using a non-CSP or conventional package, the light-emitting element 20 is formed by laying a semiconductor layer on a semiconductor board, and the semiconductor board is also used as a backing board. In contrast, in the light-emitting device using CSP, the backing board 10 is formed by putting a resin or a ceramic material on a wafer on which the light-emitting element 20 is formed. The package is thus formed in a wafer state and the light-emitting device can be produced for a low cost. Therefore it is generally referred to as a wafer-level package (WLP).

A structural feature of WLP is that the backing board 10 is so formed as to be in contact with the light-emitting element 20 or in direct contact with the protective film 60 formed on the light-emitting element 20. As the package is in contact with the light-emitting element 20, the mechanical strength of the light-emitting element 20 is reinforced and therefore a light-emitting device with high reliability can be realized. Further, as the semiconductor board is removed, height of the light-emitting device can be lowered. Further, by removing the semiconductor board, efficiency of light-extraction from the light-emitting element 20 can be improved.

Stress acting on the light-emitting element 20 significantly affects properties of the light-emitting device. In particular, as the light-emitting device to which CSP is applied has a structure in which the light-emitting element 20 is in close contact with the package material, difference in linear expansion coefficients relative to the package material or deformation during processes is likely to cause stress on the light-emitting element 20.

Therefore, as shown in FIG. 14, a ceramic board having a structure in which a first ceramic layer 11 and a second ceramic layer 12 with higher density and a larger linear expansion coefficient than those of the first ceramic layer 11 are layered may be applied to the backing board 10. As shown in FIG. 14, the light-emitting element 20 is disposed on the first ceramic layer 11 with a smaller linear expansion coefficient. As the first ceramic layer 11 having a linear expansion coefficient close to that of the semiconductor layer constituting the light-emitting element 20 is made close contact therewith in this way, distortion at a time of curing the ceramic can be relaxed and therefore the stress on the light-emitting element 20 can be reduced. Further, by applying the second ceramic layer 12 with a larger linear expansion coefficient to the side farther from the light-emitting element 20 of the backing board 10, a warp of the backing board 10 is suppressed and the strength as the totality of the package is prevented from being reduced. Therefore, by using the backing board 10 with the structure shown in FIG. 14, a light-emitting device with high reliability and high efficiency can be realized. To reduce the linear expansion coefficient and the elastic modulus of the first ceramic layer 11 includes some methods such as a method of increasing porosity.

Meanwhile in a case where a glass board is applied to the light-permeable board 70, as the glass board has a high elastic modulus and its linear expansion coefficient is very different, relatively large stress is created in the light-emitting element 20. In this case, by lowering the linear expansion coefficient of the first ceramic layer 11 than that of the second ceramic layer 12, the linear expansion coefficient of the first ceramic layer 11 can be made closer to that of the glass so that the stress on the light-emitting element 20 can be lowered.

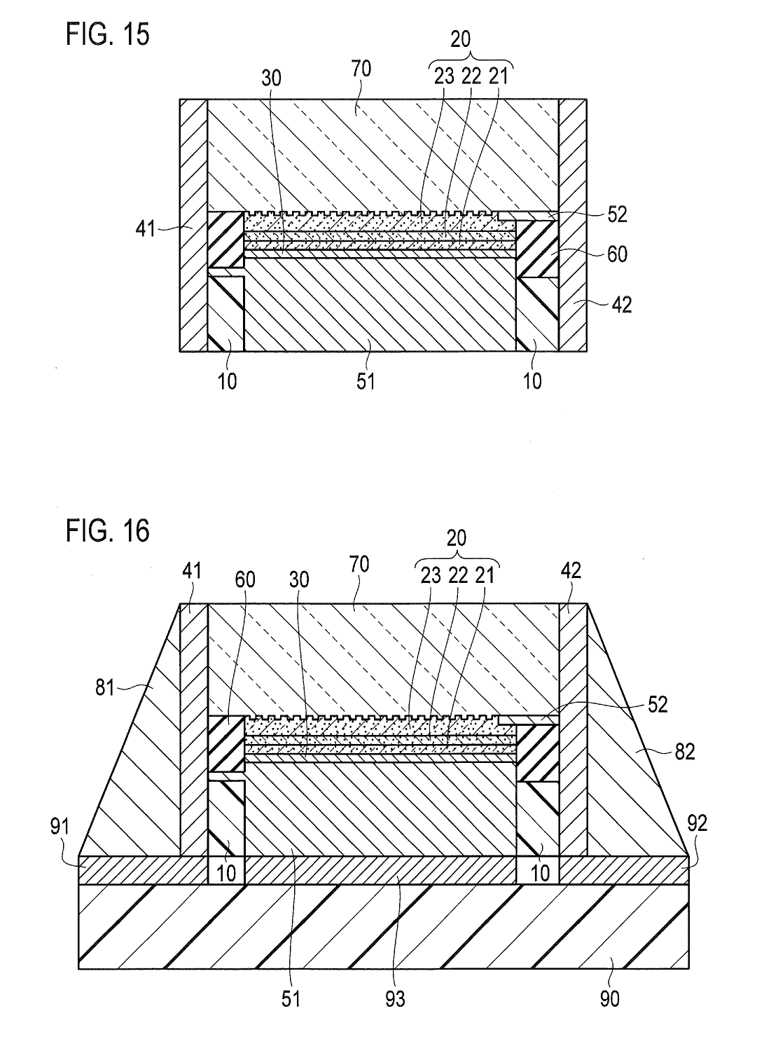

FIG. 15 shows a light-emitting device according to another embodiment. In the light-emitting device shown in FIG. 15, the first led-out electrode 51 connected to the lower face of the first semiconductor layer 21 penetrates the backing board 10. More specifically, this differs from the light-emitting device shown in FIG. 1 in that the lower face of the first led-out electrode 51 is exposed below the backing board 10. In the meantime, the structure in which the first led-out electrode 51 is elongated in a direction perpendicular to a direction of lamination of the light-emitting element 20 so as to connect with the first connecting electrode 41 is common with FIG. 1.

Further, as shown in FIG. 15, the second led-out electrode 52 is elongated from the side face of the second semiconductor layer 23 in a direction perpendicular to a direction of lamination of the light-emitting element 20 so as to connect with the second connecting electrode 42. More specifically, the elongated region is not formed in the second semiconductor layer 23. For example, a part of the semiconductor board 100 used in the production of the light-emitting element 20 may be left to serve as the second led-out electrode 52.

According to the light-emitting device shown in FIG. 15, the whole surface of the face opposed to the face from which the light is extracted out of the light-emitting element 20 is the first semiconductor layer 21 of the P-type and the first led-out electrode 51 is so disposed as to cover the whole surface of the lower face of the first semiconductor layer 21. And, the lower face of the first led-out electrode 51 with an area substantially same as that of the light-extraction face is exposed below the backing board 10.

The light-emitting layer 22 bears considerable part of heat generation from the light-emitting element 20 and in particular the electrode at the P-side mainly bears it. In the light-emitting device of the comparative example shown in FIG. 5, the heat generated in the light-emitting element 20 is radiated through the first pillar electrode 41A.

In the light-emitting device shown in FIG. 5, however, as the light-emitting layer 22 and the first semiconductor layer 21 are partly removed to form the elongated region of the second semiconductor layer 23 for connection of the second pillar electrode 42A. As the area that contributes to light emission of the light-emitting element 20 is made smaller and the efficiency of the light emission is lowered as well as the area of the first semiconductor layer 21 is reduced, the area of the first pillar electrode 41A for serving for heat radiation is reduced. As well, as the first pillar electrode 41A and the second pillar electrode 42A are extracted through a single face of the light-emitting device, it is difficult to increase the area of the first pillar electrode 41A. Therefore heat radiation form the light-emitting element 20 becomes insufficient so that efficiency of light emission and reliability are degraded.

In contrast in the light-emitting device shown in FIG. 15, heat generated in the light-emitting element 20 is transmitted through the first semiconductor layer 21 of the P-type to the first led-out electrode 51, the lower face of which is exposed out of the lower face of the backing board 10. Therefore the heat generated in the light-emitting element 20 is effectively radiated out of the light-emitting device. Therefore efficiency of light emission is improved and high reliability is obtained.

Further, in the light-emitting device shown in FIG. 15, as the elongated region is not formed in the second semiconductor layer 23, the areas of the first semiconductor layer 21, the light-emitting layer 22 and the second semiconductor layer 23 in the plan view are substantially identical. In other words, the area of the light-emitting layer 22 is comparable to the area of the light-emitting element 20 and current density can be lowered as compared with the light-emitting element 20 in which the elongated region is formed with the same chip area. Therefore a light-emitting device with high light emission efficiency and high reliability is obtained.

In the meantime, as shown in FIG. 16, it is preferable to make the lower face of the first led-out electrode 51 be in contact with a radiator plate 93 having high thermal conductivity. By making the radiator plate 93 disposed on the mounting board 90 be in contact with the first led-out electrode 51, the capacity of heat radiation by the light-emitting device can be further improved. To the radiator plate 93, any material having higher thermal conductivity such as Cu than the backing board 10 is applied.

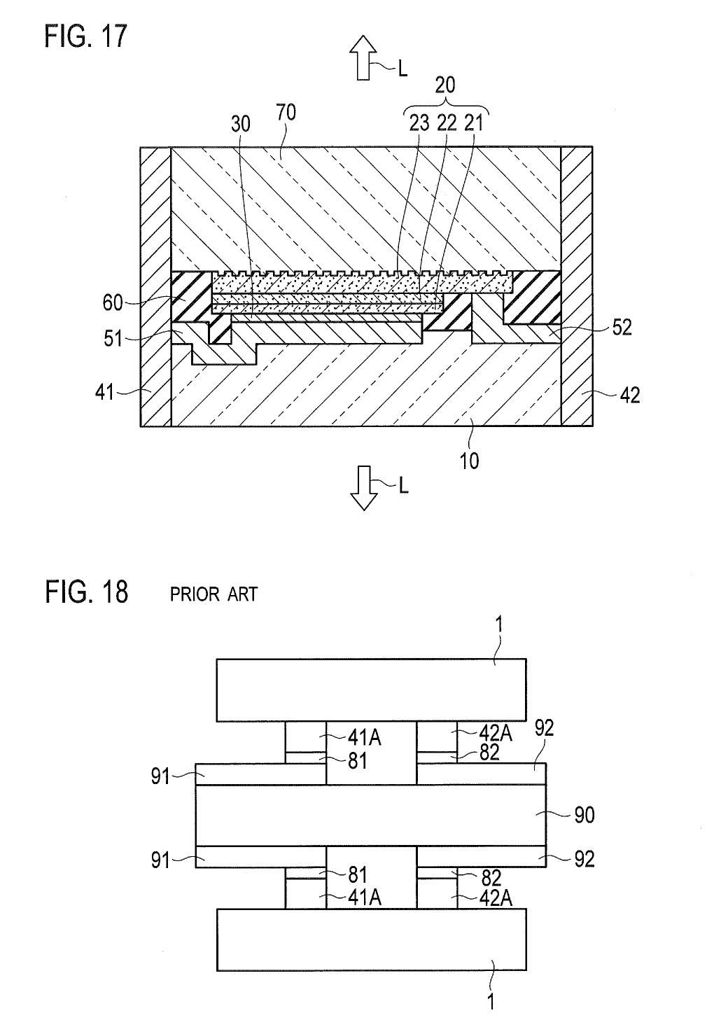

FIG. 17 shows a light-emitting device according to still another embodiment. The light-emitting device shown in FIG. 17 differs from the light-emitting device shown in FIG. 1 in that a light-permeable board is applied to the backing board 10. To the backing board 10 applicable is any board having properties similar to those of the light-permeable board 70, and a glass board for example is preferably used.

In the light-emitting device shown in FIG. 17, the outgoing light from the light-emitting element 20 permeates the backing board 10 and is then output to the exterior of the light-emitting device. In other words, the output light L is output through all the faces except the face on which the connecting electrodes are disposed. In this way, according to the light-emitting device shown in FIG. 17, a light-emitting device of a filament type can be realized.

On the other hand, to realize a light-emitting device of a filament type by the light-emitting device of the comparable example shown in FIG. 5, as shown in FIG. 18, light-emitting devices 1 are required to be disposed respectively on distinct faces of the mounting board 90.

In contrast in the light-emitting device shown in FIG. 17, the light-emitting device of the filament type can be realized only with the single light-emitting device. Therefore a small-sized light-emitting device with low electric power consumption can be realized. To produce the light-emitting device shown in FIG. 17, in the step described with reference to FIG. 8, low-melting-point glass is formed into a predetermined shape to produce the backing board 10 for example.

There may be still more variations or modifications.

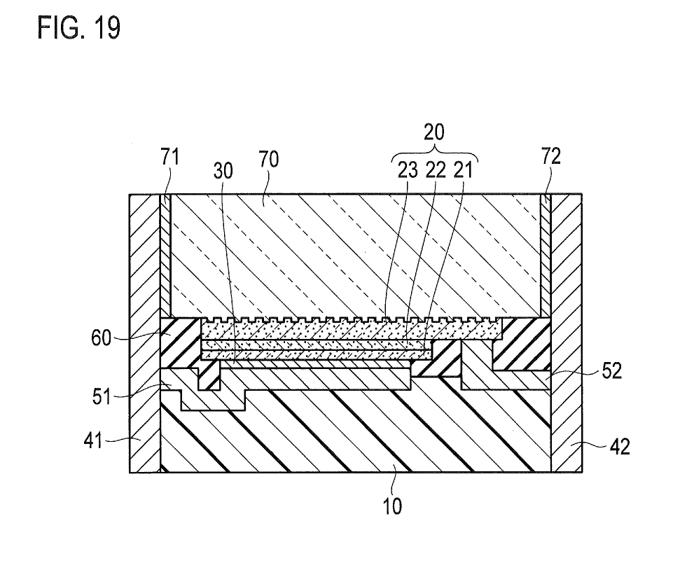

For example, the interfaces between the connecting electrodes and the light-permeable board 70 may be so constituted as to output the outgoing light from the light-emitting element 20. By this, brightness of the output light L from the light-emitting device can be improved. As shown in FIG. 19 for example, light reflective films 71, 72, which reflect the outgoing light from the light-emitting element 20, are disposed in between the connecting electrodes and the light-permeable board 70. To the light reflective films 71, 72, any metal films such as aluminum (Al) films are applicable. Or, it may be so configured that the interfaces reflect the outgoing light from the light-emitting element 20 by using difference in index of refraction between the connecting electrodes and the light-permeable board 70.

Although certain exemplary embodiments have been described above, modifications and variations of the embodiments described above will occur to those skilled in the art, in light of the above teachings.

### INDUSTRIAL APPLICABILITY

The semiconductor device as described above is applicable to use for a light-emitting device to which CSP is applied.

What is claimed is:

1. A light-emitting device connected to a mounting board, comprising:
a backing board;
a light-emitting element disposed on the backing board, the light-emitting element having a laminate structure in which a second semiconductor layer is disposed above a first semiconductor layer;
a light-permeable board disposed over the light-emitting element;
a first connecting electrode so continuously disposed as to range from a first side face of the backing board to a first side face of the light-permeable board and electrically connected to the first semiconductor layer; and
a second connecting electrode so continuously disposed as to range from a second side face of the backing board to a second side face of the light-permeable board and electrically connected to the second semiconductor layer,
wherein connection to the mounting board is established via a second side face of the first connecting electrode and the second connecting electrode, the second side being opposed to a first side face looking to the backing board and the light-permeable board.

2. The light-emitting device of claim 1, wherein the first connecting electrode and the second connecting electrode are respectively connected to a wiring pattern disposed on the mounting board by means of a first bonding component disposed on the second side face of the first connecting electrode and a second bonding component disposed on the second side face of the second connecting electrode.

3. The light-emitting device of claim 2, wherein the light-permeable board has thermal resistance to a temperature for forming connection among the first connecting electrode, the second connecting electrode and the wiring pattern by means of the first bonding component and the second bonding component.

4. The light-emitting device of claim 3, wherein the light-permeable board is a glass board.

5. The light-emitting device of claim 1, wherein the backing board is a ceramic board.

6. The light-emitting device of claim 5, wherein the ceramic board has a structure in which a first ceramic layer and a second ceramic layer having a linear expansion coefficient greater than the first ceramic layer are stacked and the light-emitting element is disposed on the first ceramic layer.

7. The light-emitting device of claim 1, wherein a lower face of the light-emitting element is covered with the backing board totally in a plan view.

8. The light-emitting device of claim 1, further comprising:
a first led-out electrode connected to a lower face of the first semiconductor layer and elongated in a direction perpendicular to a direction of lamination of the light-emitting element so as to connect with the first connecting electrode, wherein a lower face of the first led-out electrode is exposed below the backing board.

9. The light-emitting device of claim 1, further comprising:
a second led-out electrode elongated from a side face of the second semiconductor layer in a direction perpendicular to a direction of lamination of the light-emitting element and electrically connecting the second semiconductor layer with the second connecting electrode.

10. The light-emitting device of claim 1, wherein the backing board has light-permeability.

11. The light-emitting device of claim 1, wherein an interface between the first and second connecting electrodes and the light-permeable board is so configured as to reflect outgoing light from the light-emitting element.
